(19) United States
(12) Patent Application Publication
(10) Pub. No.: US 2017/0140974 A1
(43) Pub. Date: May 18, 2017

(54) LAMINATED BODY AND COMPOSITE BODY; ASSEMBLY RETRIEVAL METHOD; AND SEMICONDUCTOR DEVICE MANUFACTURING METHOD

(71) Applicant: NITTO DENKO CORPORATION, Osaka (JP)

(72) Inventors: Ryuichi KIMURA, Ibaraki-shi (JP); Naohide TAKAMOTO, Ibaraki-shi (JP)

(73) Assignee: NITTO DENKO CORPORATION, Osaka (JP)

(21) Appl. No.: 15/349,172

(22) Filed: Nov. 11, 2016

(30) Foreign Application Priority Data
Nov. 13, 2015 (JP) 2015-222919

(51) Int. Cl. H01L 21/683; B32B 7/12; H01L 21/78

(52) U.S. Cl. CPC H01L 21/6836; H01L 21/78; B32B 7/12; B32B 2255/26; B32B 2255/28; B32B 2307/748; B32B 2307/51; B32B 2457/14

(57) ABSTRACT

[PROBLEM] To provide a laminated body and so forth that makes it possible to prevent pieces of post-dicing semiconductor backside protective film from sticking to one another.

[SOLUTION MEANS] This relates to a laminated body comprising a two-sided adhesive sheet and a semiconductor backside protective film arranged over the two-sided adhesive sheet. The two-sided adhesive sheet comprises a first adhesive layer, a second adhesive layer, and a base layer. The base layer is disposed between the first adhesive layer and the second adhesive layer. The first adhesive layer has a property such that application of heat causes reduction in the peel strength thereof. The first adhesive layer is disposed between the semiconductor backside protective film and the base layer.

### TECHNICAL FIELD

The present invention relates to a laminated body, a composite body, an assembly retrieval method, and a semiconductor device manufacturing method.

### BACKGROUND ART

Semiconductor backside protective films serve to reduce warpage of semiconductor wafers and to protect the backsides thereof.

Methods in which semiconductor backside protective film and dicing tape are handled in integral fashion are known. For example, there is a method in which a semiconductor wafer is secured to a semiconductor backside protective film that is secured to dicing tape, dicing is carried out to form assemblies comprising chips and diced semiconductor backside protective film, needles are used to push up the dicing tape and expand the dicing tape, and the assemblies are detached from the dicing tape.

### PRIOR ART REFERENCES

### Patent References

PATENT REFERENCE NO. 1: Japanese Patent Application Publication Kokai No. 2012-33636

### SUMMARY OF INVENTION

### Problem to be Solved by Invention

When using the aforementioned method, pieces of post-dicing semiconductor backside protective film may stick to one another before pick-up can be carried out. This can happen because after the dicing tape is expanded the dicing tape contracts; i.e., the distance between adjacent pieces of post-dicing semiconductor backside protective film decreases. If pieces of post-dicing semiconductor backside protective film stick to one another, this will cause decrease in pick-up success rate.

It is an object of the present invention to provide a laminated body that makes it possible to prevent pieces of post-dicing semiconductor backside protective film from sticking to one another. It is an object of the present invention to provide a composite body that makes it possible to prevent pieces of post-dicing semiconductor backside protective film from sticking to one another. It is an object of the present invention to provide a method that makes it possible to prevent pieces of post-dicing semiconductor backside protective film from sticking to one another.

### Means for Solving Problem

The present invention relates to a laminated body comprising a two-sided adhesive sheet and a semiconductor backside protective film arranged over the two-sided adhesive sheet. The two-sided adhesive sheet comprises a first adhesive layer, a second adhesive layer, and a base layer. The base layer is disposed between the first adhesive layer and the second adhesive layer. The first adhesive layer has a property such that application of heat causes reduction in the peel strength thereof. The first adhesive layer is disposed between the semiconductor backside protective film and the base layer.

When dicing a semiconductor wafer at which there is a hard support body secured to the second adhesive layer, it will be possible to prevent adjacent pieces of post-dicing semiconductor backside protective film from sticking to one another. This is so because the hard support body does not undergo contraction. What is more, the assembly can be detached from the two-sided adhesive tape without the need to cause expansion thereof. This is because the first adhesive layer has a property such that heat causes reduction in the peel strength thereof.

The present invention also relates to a composite body comprising a release liner and a laminated body arranged over the release liner.

The present invention also relates to a method for retrieving an assembly comprising a semiconductor chip and a post-dicing semiconductor backside protective film secured to the semiconductor chip. The assembly retrieval method comprises an operation (A) in which a semiconductor wafer is secured to semiconductor backside protective film at a laminated body; an operation (B) in which a hard support body is secured to a second adhesive layer of the laminated body; an operation (C) in which the semiconductor wafer secured to the semiconductor backside protective film is subjected to dicing to form an assembly; an operation (D) in which the two-sided adhesive sheet is heated following Operation (C); and an Operation (E) in which the assembly is detached from the two-sided adhesive sheet following Operation (D).

The present invention also relates to a semiconductor device manufacturing method comprising Operation (A) through Operation (E). The semiconductor device manufacturing method further comprises an Operation (F) in which the assembly is secured to an object to be bonded.

### BRIEF DESCRIPTION OF DRAWINGS

FIG. 1 Schematic plan view of a composite body.

FIG. 2 Schematic sectional diagram of a portion of a composite body.

FIG. 3 Schematic sectional diagram showing an operation for manufacturing a semiconductor device.

FIG. 4 Schematic sectional diagram showing an operation for manufacturing a semiconductor device.

FIG. 5 Schematic sectional diagram showing an operation for manufacturing a semiconductor device.

FIG. 6 Schematic sectional diagram showing an operation for manufacturing a semiconductor device.

FIG. 7 Schematic sectional diagram showing the laminated body of Variation 1.

FIG. 8 Schematic sectional diagram showing the laminated body of Variation 2.

FIG. 9 Schematic sectional diagram showing a portion of the composite body of Variation 3.

### EMBODIMENTS FOR CARRYING OUT INVENTION

Although the present invention is described in detail below in terms of embodiments, it should be understood that the present invention is not limited only to these embodiments.

### Embodiment 1

### —Composite Body 1—

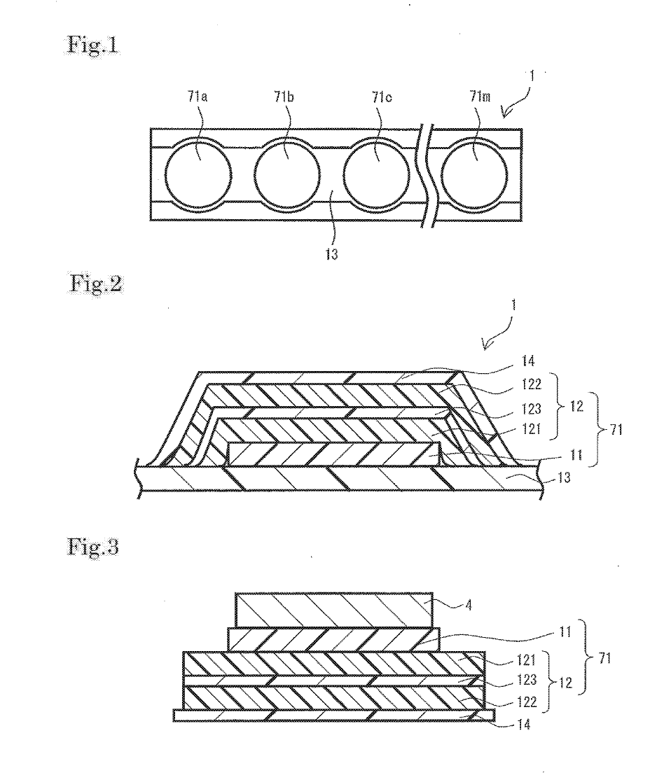

As shown in FIG. 1 and FIG. 2, composite body 1 comprises release liner 13 and laminated bodies 71a, 71b, 71c, . . . 71m (hereinafter collectively referred to as “laminated bodies 71”) which are arranged over release liner 13. The distance between laminated body 71a and laminated body 71b, the distance between laminated body 71b and laminated body 71c, . . . and the distance between laminated body 71l and laminated body 71m, is constant. Composite body 1 further comprises release liner 14 which is respectively arranged over plurality of laminated bodies 71. Composite body 1 may be in the form of a roll.

Laminated bodies 71 comprise two-sided adhesive sheet 12 and semiconductor backside protective film 11 which is arranged over two-sided adhesive sheet 12.

Two-sided adhesive sheet 12 comprises first adhesive layer 121, second adhesive layer 122, and base layer 123 which is disposed between first adhesive layer 121 and second adhesive layer 122. First adhesive layer 121 is disposed between semiconductor backside protective film 11 and base layer 123. First adhesive layer 121 is in contact with semiconductor backside protective film 11. First adhesive layer 121 is in contact with base layer 123. The two sides of two-sided adhesive sheet 12 may be defined such that there is a first side and a second side opposite the first side. The first side of two-sided adhesive sheet 12 is the side thereof that is in contact with semiconductor backside protective film 11.

It is preferred that the peel strength (23° C.; 180° peel angle; 300 mm/min peel rate) between semiconductor backside protective film 11 and two-sided adhesive sheet 12 be 0.05 N/20 mm to 5 N/20 mm. When this is 0.05 N/20 mm or greater, semiconductor backside protective film 11 tends not to detach from two-sided adhesive sheet 12 during dicing.

### —First Adhesive Layer 121—

First adhesive layer 121 has a property such that application of heat causes reduction in the peel strength thereof. For example, this may be a property such that application of heat causes foaming. Following foaming, semiconductor backside protective film 11 can be easily detached from two-sided adhesive sheet 12.

First adhesive layer 121 may comprise an adhesive in which the base polymer thereof is a polymer for which the dynamic modulus of elasticity in the temperature domain from normal temperature to 150° C. is 50,000 dyn/cm² to 10,000,000 dyn/cm². For example, this might be an acrylic adhesive in which the base polymer thereof is an acrylic polymer employing one, two, or more varieties of (meth)acrylic acid alkyl ester as monomer component(s).

First adhesive layer 121 comprises thermally expansible microspheres. The thermally expansible microspheres have a property such that they expand as a result of application of heat. Following expansion of the thermally expansible microspheres, semiconductor backside protective film 11 can be easily detached from two-sided adhesive sheet 12. This is due to deformation of first adhesive layer 121. The thermally expansible microspheres may comprise a substance that is transformed into a gas as a result of application of heat, and microcapsule(s) that encapsulate the substance that is transformed into a gas as a result of application of heat. The substance that is transformed into a gas as a result of application of heat might, for example, be isobutane, propane, pentane, or the like. The microcapsule(s) may comprise high-molecular-weight compound(s). For example, this might be vinylidene chloride-acrylonitrile copolymer, polyvinyl alcohol, polyvinyl butyral, polymethyl methacrylate, polyacrylonitrile, polyvinylidene chloride, polysulfone, and/or the like. Of these, high-molecular-weight thermoplastic resin(s) are preferred. Commercially available thermally expansible microspheres include microspheres sold by Matsumoto Yushi-Seiyaku Co., Ltd and the like.

It is preferred that the temperature for initiating thermal expansion of the thermally expansible microspheres be not less than 90° C. At 90° C. and higher, expansion due to heat acting on first adhesive layer 121 at or before the pick-up operation does not tend to occur. It is preferred that bulk modulus of the thermally expansible microspheres be not less than 5, more preferred that this be not less than 7, and still more preferred that this be not less than 10. It is preferred that average particle diameter of the thermally expansible microspheres be not greater than 100 μm, more preferred that this be not greater than 80 μm, and still more preferred that this be not greater than 50 μm. The lower limit of the range in values for average particle diameter of the thermally expansible microspheres might, for example, be 1 μm. For every 100 parts by weight of the base polymer, it is preferred that the thermally expansible microspheres be present in an amount that is not less than 1 part by weight, more preferred that this be not less than 10 parts by weight, and still more preferred that this be not less than 25 parts by weight. For every 100 parts by weight of the base polymer, it is preferred that the thermally expansible microspheres be present in an amount that is not greater than 150 parts by weight, more preferred that this be not greater than 130 parts by weight, and still more preferred that this be not greater than 100 parts by weight.

It is preferred that thickness of first adhesive layer 121 be not less than 2 μm, and more preferred that this be not less than 5 μm. It is preferred that thickness of first adhesive layer 121 be not greater than 300 μm, more preferred that this be not greater than 200 μm, and still more preferred that this be not greater than 150 μm.

### —Second Adhesive Layer 122—

Second adhesive layer 122 comprises an acrylic adhesive or other such adhesive. Second adhesive layer 122 does not have a property such that it expands as a result of application of heat. It is preferred that thickness of second adhesive layer 122 be not less than 2 μm, and more preferred that this be not less than 5 μm. It is preferred that thickness of second adhesive layer 122 be not greater than 300 μm, more preferred that this be not greater than 200 μm, and still more preferred that this be not greater than 150 μm.

### —Base Layer 123—

It is preferred that base layer 123 have a property such that a laser is transmitted therethrough (hereinafter “laser transmittance”). Semiconductor backside protective film 11 may be irradiated by a laser which is made to pass through base layer 123.

It is preferred that thickness of base layer 123 be not less than 1 μm, more preferred that this be not less than 10 μm, still more preferred that this be not less than 20 μm, and even more preferred that this be not less than 30 μm. It is preferred that thickness of base layer 123 be not greater than 1000 μm, more preferred that this be not greater than 500 μm, still more preferred that this be not greater than 300 μm, and even more preferred that this be not greater than 200 μm.

### —Semiconductor Backside Protective Film 11—

The two sides of semiconductor backside protective film 11 may be defined such that there is a first principal plane and a second principal plane opposite the first principal plane. The first principal plane is in contact with first adhesive layer 121. The second principal plane is in contact with release liner 13.

Semiconductor backside protective film 11 is colored. If this is colored, it may be possible to easily distinguish between two-sided adhesive sheet 12 and semiconductor backside protective film 11. It is preferred that semiconductor backside protective film 11 be black, blue, red, or some other deep color. It is particularly preferred that this be black. The reason for this is that this will facilitate visual recognition of laser mark(s).

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

It is preferred that moisture absorptivity of semiconductor backside protective film 11 when allowed to stand for 168 hours under conditions of 85° C. and 85% RH be not greater than 1 wt/o, and it is more preferred that this be not greater than 0.8 wt %/o. By causing this to be not greater than 1 wt %, it is possible to improve laser marking characteristics. Moisture absorptivity can be controlled by means of inorganic filler content and so forth. A method for measuring moisture absorptivity of semiconductor backside protective film 11 is as follows. That is, semiconductor backside protective film 11 is allowed to stand for 168 hours in a constant-temperature/constant-humidity chamber at 85° C. and 85% RH, following which moisture absorptivity is determined from the percent weight loss as calculated based on measurements of weight before and after being allowed to stand.

Semiconductor backside protective film 11 is in an uncured state. Uncured state includes semicured state. A semicured state is preferred.

It is preferred that moisture absorptivity of the cured substance obtained when semiconductor backside protective film 11 is cured and this is allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. Moisture absorptivity can be controlled by means of inorganic filler content and so forth. A method for measuring moisture absorptivity of the cured substance is as follows. That is, the cured substance is allowed to stand for 168 hours in a constant-temperature/constant-humidity chamber at 85° C. and 85% RH, following which moisture absorptivity is determined from the percent weight loss as calculated based on measurements of weight before and after being allowed to stand.

The smaller the percentage of volatile components present in semiconductor backside protective film 11 the better. More specifically, it is preferred that the percent weight loss (fractional decrease in weight) of semiconductor backside protective film 11 following heat treatment be not greater than 1 wt %, and it is more preferred that this be not greater than 0.8 wt %. Conditions for carrying out heat treatment might, for example, be 1 hour at 250° C. Causing this to be not greater than 1 wt % will result in good laser marking characteristics. There may be reduced occurrence of cracking during the reflow operation. What is referred to as percent weight loss is the value obtained when semiconductor backside protective film 11 is thermally cured and is thereafter heated at 250° C. for 1 hour.

It is preferred that the tensile storage modulus at 23° C. of semiconductor backside protective film 11 when in an uncured state be not less than 1 GPa, more preferred that this be not less than 2 GPa, and still more preferred that this be not less than 3 GPa. Causing this to be not less than 1 GPa will make it possible to prevent semiconductor backside protective film 11 from adhering to the carrier tape. The upper limit of the range in values for the tensile storage modulus at 23° C. thereof might, for example, be 50 GPa. The tensile storage modulus at 23° C. thereof can be controlled by means of the type(s) of resin component(s) and amount(s) in which present, the type(s) of filler(s) and amount(s) in which present, and so forth. Tensile storage modulus is measured using a “Solid Analyzer RS A2” dynamic viscoelasticity measuring device manufactured by Rheometric, Inc., in tensile mode, with sample width=10 mm, sample length=22.5 mm, sample thickness=0.2 mm, frequency=1 Hz, and temperature rise rate=10° C./min in a nitrogen atmosphere at prescribed temperature (23° C.).

While there is no particular limitation with respect to the optical transmittance for a visible light beam (wavelength=380 nm to 750 nm) (visible light transmittance) of semiconductor backside protective film 11, it is for example preferred that this be within a range such that it is not greater than 20% (0% to 20%), more preferred that this be not greater than 10% (0% to 10%), and especially preferred that this be not greater than 5% (0% to 5%). If semiconductor backside protective film 11 has a visible light transmittance that is greater than 20%, there is a possibility that this will have an adverse effect on the semiconductor chip(s) due to passage of light beam(s) therethrough. Furthermore, the visible light transmittance (%) thereof can be controlled by means of the type(s) of resin component(s) and amount(s) in which present, the type(s) of colorant(s) (pigment(s), dye(s), and/or the like) and amount(s) in which present, the amount(s) in which inorganic filler(s) are present, and so forth at semiconductor backside protective film 11.

Visible light transmittance (%) of semiconductor backside protective film 1 may be measured as follows. That is, semiconductor backside protective film 11, of thickness (average thickness) 20 μm, is fabricated by itself. Next, the semiconductor backside protective film 11 is irradiated with a visible light beam of wavelength=380 nm to 750 nm (device=visible light generator manufactured by Shimadzu Corporation; product name “ABSORPTION SPECTRO PHOTOMETER”) and prescribed intensity, and intensity of the visible light beam that is transmitted therethrough is measured. Moreover, the value for visible light transmittance may be determined from the change in intensity as calculated based on measurements of a visible light beam before and after being transmitted through semiconductor backside protective film 11.

It is preferred that semiconductor backside protective film 11 comprise colorant. Colorant might, for example, be dye(s) and/or pigment(s). Of these, dye(s) are preferred, and black dye(s) are more preferred.

It is preferred that colorant(s) be present in semiconductor backside protective film 11 in an amount that is not less than 0.5 wt %, more preferred that this be not less than 1 wt %, and still more preferred that this be not less than 2 wt %. It is preferred that colorant(s) be present in semiconductor backside protective film 11 in an amount that is not greater than 10 wt %, more preferred that this be not greater than 8 wt %, and still more preferred that this be not greater than 5 wt %.

Semiconductor backside protective film 11 may comprise thermoplastic resin. As thermoplastic resin, natural rubber; butyl rubber; isoprene rubber; chloroprene rubber, ethylene-vinyl acetate copolymer; ethylene-acrylic acid copolymer; ethylene-acrylic acid ester copolymer; polybutadiene resin; polycarbonate resin; thermoplastic polyimide resin; nylon 6, nylon 6,6, and other such polyamide resins; phenoxy resin; acrylic resin; PET (polyethylene terephthalate), PBT (polybutylene terephthalate), and other such saturated polyester resins; polyamide-imide resin; fluorocarbon resin; and the like may be cited as examples. Any one of these thermoplastic resins may be used alone, or two or more species chosen from thereamong may be used in combination. Of these, acrylic resin and phenoxy resin are preferred.

It is preferred that thermoplastic resin be present in semiconductor backside protective film 11 in an amount that is not less than 10 wt %, and it is more preferred that this be not less than 30 wt %. It is preferred that thermoplastic resin be present in semiconductor backside protective film 11 in an amount that is not greater than 90 wt %, and it is more preferred that this be not greater than 70 wt %.

Semiconductor backside protective film 11 may comprise thermosetting resin. As thermosetting resin, epoxy resin, phenolic resin, amino resin, unsaturated polyester resin, polyurethane resin, silicone resin, thermosetting polyimide resin, and so forth may be cited as examples. Any one of these thermosetting resins may be used alone, or two or more species chosen from thereamong may be used in combination. As thermosetting resin, epoxy resin having low content of ionic impurities and/or other substances causing corrosion of semiconductor chips is particularly preferred. Furthermore, as curing agent for epoxy resin, phenolic resin may be preferably employed.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

It is preferred that thermosetting resin be present in semiconductor backside protective film 11 in an amount that is not less than 2 wt %, and it is more preferred that this be not less than 5 wt %. It is preferred that thermosetting resin be present in semiconductor backside protective film 11 in an amount that is not greater than 40 wt %, and it is more preferred that this be not greater than 20 wt %.

Semiconductor backside protective film 11 may comprise curing accelerator catalyst. For example, this might be amine-type curing accelerator, phosphorous-type curing accelerator, imidazole-type curing accelerator, boron-type curing accelerator, phosphorous-/boron-type curing accelerator, and/or the like.

To cause semiconductor backside protective film 11 to undergo crosslinking to a certain extent in advance, it is preferred that polyfunctional compound(s) that react with functional group(s) and/or the like at end(s) of polymer molecule chain(s) be added as crosslinking agent at the time of fabrication thereof. This will make it possible to improve adhesion characteristics at high temperatures and to achieve improvements in heat-resistance.

Semiconductor backside protective film 11 may comprise filler. Inorganic filler is preferred. This inorganic filler might, for example, be silica, clay, gypsum, calcium carbonate, barium sulfate, alumina, beryllium oxide, silicon carbide, silicon nitride, aluminum, copper, silver, gold, nickel, chromium, lead, tin, zinc, palladium, solder, and/or the like. Any one of these fillers may be used alone, or two or more species chosen from thereamong may be used in combination. Of these, silica is preferred, and fused silica is particularly preferred. It is preferred that average particle diameter of inorganic filler be within the range 0.1 μm to 80 μm. Average particle diameter of inorganic filler might, for example, be measured using a laser-diffraction-type particle size distribution measuring device.

It is preferred that filler be present in semiconductor backside protective film 11 in an amount that is not less than 10 wt %, and it is more preferred that this be not less than 20 wt %. It is preferred that filler be present in semiconductor backside protective film 11 in an amount that is not greater than 70 wt %, and it is more preferred that this be not greater than 50 wt %.

Semiconductor backside protective film 11 may comprise other additive(s) as appropriate. As other additive(s), flame retardant, silane coupling agent, ion trapping agent, expander, antioxidizer, antioxidant, surface active agent, and so forth may be cited as examples.

It is preferred that thickness of semiconductor backside protective film 11 be not less than 2 μm, more preferred that this be not less than 4 μm, still more preferred that this be not less than 6 μm, and particularly preferred that this be not less than 10 Gm. It is preferred that thickness of semiconductor backside protective film 11 be not greater than 200 μm, more preferred that this be not greater than 160 μm, still more preferred that this be not greater than 100 μm, and particularly preferred that this be not greater than 80 μm.

### —Release Liner 14—

Release liner 14 might, for example, be polyethylene terephthalate (PET) film.

### —Release Liner 13—

Release liner 13 might, for example, be polyethylene terephthalate (PET) film.

### —Semiconductor Device Manufacturing Method—

As shown in FIG. 3, semiconductor wafer 4 is secured to semiconductor backside protective film 11 of laminated bodies 71. More specifically, a pressure roller or other such pressure-applying means is used to compression-bond laminated bodies 71 onto semiconductor wafer 4 at 50° C. to 100° C. The two sides of semiconductor wafer 4 may be defined such that there is a circuit side and a backside (also referred to as non-circuit side or non-electrode-forming side) opposite the circuit side. Semiconductor wafer 4 might, for example, be a silicon wafer.

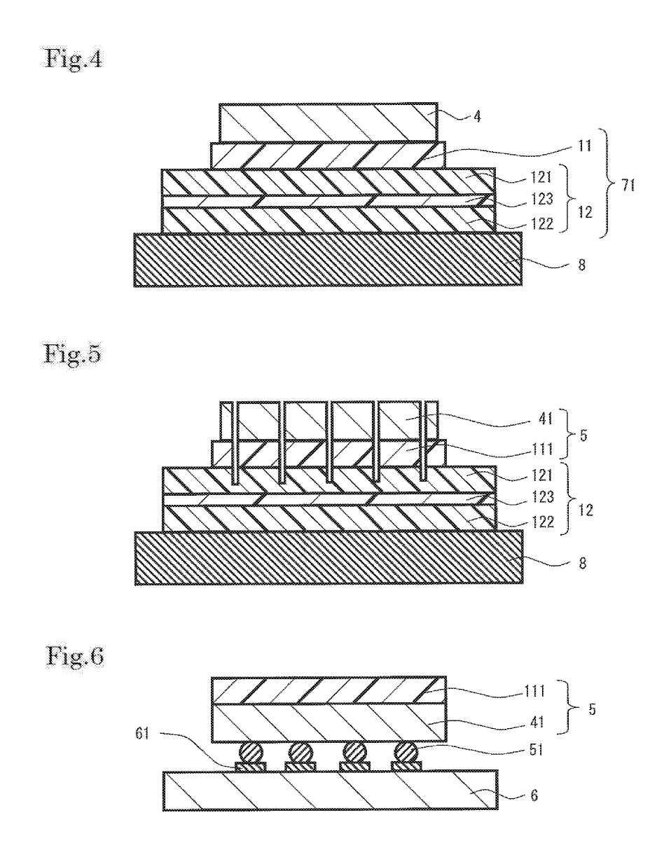

As shown in FIG. 4, release liner 14 is detached, and hard support body 8 is secured to second adhesive layer 122. More specifically, support body 8 is secured to second adhesive layer 122 by pressing support body 8 against second adhesive layer 122 on a parallel plate under vacuum conditions. By pressing support body 8 against second adhesive layer 122 under vacuum conditions, it is possible to reduce bubbles therein. Support body 8 is planar. It is preferred that this be smooth and flat. Support body 8 might, for example, be a metal plate, a ceramic plate, a glass plate, or the like. It is preferred that support body 8 be transparent to laser light. Where this is the case, this is so as to permit semiconductor backside protective film 11 to be irradiated by a laser which is made to pass through support body 8. Thickness of support body 8 might, for example, be 0.1 mm to 10 mm.

As shown in FIG. 5, assemblies 5 are formed as a result of dicing of semiconductor wafer 4. Assembly 5 comprises semiconductor chip 41 and post-dicing semiconductor backside protective film 111 which is secured to the backside of semiconductor chip 41. The two sides of semiconductor chip 41 may be defined such that there is a circuit side and a backside opposite the circuit side. Assembly 5 is secured to two-sided adhesive sheet 12.

The peel strength between assembly 5 and two-sided adhesive sheet 12 is lowered. More specifically, a heater directed at support body 8 causes heat to be applied to two-sided adhesive sheet 12, as a result of which peel strength is lowered. That is, application of heat causes expansion of first adhesive layer 121. Here, it is preferred that this be heated to a temperature that is not less than 50° C. higher than the temperature for initiating expansion of the thermally expansible microspheres. This might, for example, be 100° C. to 250° C.

A vacuum suction collet is used to detach assembly 5 from first adhesive layer 121. That is, pick-up of assembly 5 is carried out.

As shown in FIG. 6, the flip-chip bonding technique (flip-chip mounting technique) is employed to cause assembly 5 to be secured to object 6 to be bonded. More specifically, assembly 5 is secured to object 6 to be bonded in such fashion that the circuit side of semiconductor chip 41 is opposed to object 6 to be bonded. For example, bump 51 of semiconductor chip 41 might be made to come in contact with electrically conductive material (solder or the like) 61 of object 6 to be bonded, and while pushing this thereagainst, electrically conductive material 61 might be made to melt. There is a gap between assembly 5 and object 6 to be bonded. Height of this gap might typically be on the order of 30 μm to 300 μm. Following securing of constituent parts, it is possible to carry out cleaning of the gap and so forth.

As object 6 to be bonded, a lead frame, circuit board (wiring circuit board), or other such substrate may be employed. As material for such substrate, while there is no particular limitation with respect thereto, ceramic substrate and plastic substrate may be cited as examples. As plastic substrate, epoxy substrate, bismaleimide triazine substrate, polyimide substrate, and the like may be cited as examples.

As material for the bump and/or electrically conductive material, there is no particular limitation with respect thereto, it being possible to cite examples that include tin-lead-type metallic materials, tin-silver-type metallic materials, tin-silver-copper-type metallic materials, tin-zinc-type metallic materials, tin-zinc-bismuth-type metallic materials, and other such solders (alloys), gold-type metallic materials; and copper-type metallic materials. Note that temperature at the time of melting of electrically conductive material 61 might ordinarily be on the order of 260° C. If post-dicing semiconductor backside protective film 111 comprises epoxy resin, it will be able to withstand such temperatures.

The gap between assembly 5 and object 6 to be bonded is sealed with resin sealant. Resin sealant might ordinarily be cured by heating for 60 seconds to 90 seconds at 175° C. This heating may also cause thermal curing of post-dicing semiconductor backside protective film 111.

As resin sealant, so long as it is a resin that has insulating characteristics (insulating resin), there is no particular limitation with respect thereto. As resin sealant, it is more preferred that this be an insulating resin that has elasticity. As resin sealant, resin compositions comprising epoxy resins and the like may be cited as examples. Furthermore, as resin sealant which is a resin composition comprising epoxy resin, the resin component thereof may, besides epoxy resin, comprise thermosetting resin other than epoxy resin (phenolic resin and/or the like), thermoplastic resin, and/or the like. Where phenolic resin is employed, note that this may also serve as curing agent for epoxy resin. Resin sealant may take the form of sheet(s), tablet(s), and/or the like.

A semiconductor device (flip-chip-mounted semiconductor device) manufactured in accordance with the foregoing method comprises object 6 to be bonded and assembly 5 secured to object 6 to be bonded.

A laser may be used to carry out marking of post-dicing semiconductor backside protective film 111 of the semiconductor device. Note that known laser marking apparatuses may be employed when carrying out laser marking. Furthermore, as laser, gas lasers, solid-state lasers, liquid lasers, and the like may be employed. More specifically, as gas laser, while there is no particular limitation with respect thereto and any known gas laser may be employed, carbon dioxide gas lasers (CO₂ lasers) and excimer lasers (ArF lasers, KrF lasers, XeCl lasers, XeF lasers, etc.) are preferred. Furthermore, as solid-state laser, while there is no particular limitation with respect thereto and any known solid-state laser may be employed, YAG lasers (Nd:YAG lasers, etc.) and YVO₄ lasers are preferred.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

### —Variation 1—

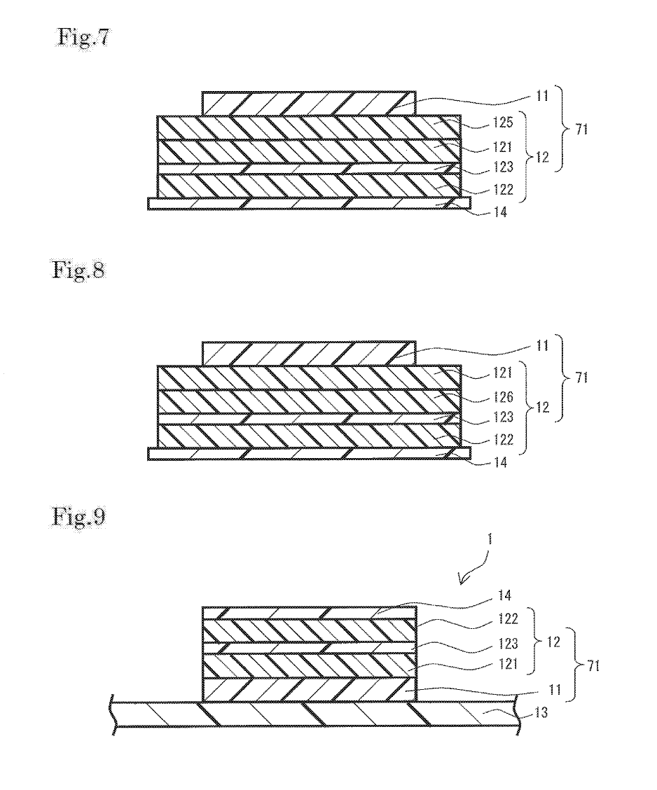

As shown in FIG. 7, two-sided adhesive sheet 12 further comprises non-thermally-expansible third adhesive layer 125. Third adhesive layer 125 is disposed between first adhesive layer 121 and semiconductor backside protective film 11. Third adhesive layer 125 does not have a property such that it expands as a result of application of heat. Contaminants-gas, organic components, and so forth-generated at the time of expansion of thermally expansible microspheres are prevented from migrating from first adhesive layer 121 to semiconductor backside protective film 11 by third adhesive layer 125.

### —Variation 2—

As shown in FIG. 8, two-sided adhesive sheet 12 further comprises rubber-like organic elastic layer 126 which is disposed between first adhesive layer 121 and base layer 123. Rubber-like organic elastic layer 126 may prevent deformation produced by first adhesive layer 121 as a result of expansion from propagating to second adhesive layer 122 and/or the like. Rubber-like organic elastic layer 126 does not have a property such that it expands as a result of application of heat. Principal constituent(s) of rubber-like organic elastic layer 126 is/are synthetic rubber, synthetic resin, and/or the like. It is preferred that thickness of rubber-like organic elastic layer 126 be not less than 3 μm, and more preferred that this be not less than 5 μm. It is preferred that thickness of rubber-like organic elastic layer 126 be not greater than 500 μm, more preferred that this be not greater than 300 μm, and still more preferred that this be not greater than 150 μm.

### —Variation 3—

As shown in FIG. 9, the entire surface of one side of first adhesive layer 121 is in contact with semiconductor backside protective film 11.

### —Variation 4—

After support body 8 is secured to second adhesive layer 122, marking of semiconductor backside protective film 11 is carried out by a laser which is made to pass through support body 8. After marking is carried out, assembly 5 is formed.

### —Variation 5—

Following formation of assembly 5, a laser is used to carry out marking of post-dicing semiconductor backside protective film 111. After marking is carried out, two-sided adhesive sheet 12 is heated.

### —Variation 6—

Following heating of two-sided adhesive sheet 12, a laser is used to carry out marking of post-dicing semiconductor backside protective film 11. After marking is carried out, assembly 5 is detached from first adhesive layer 121.

### —Miscellaneous—

Any of Variation 1 through Variation 6 and/or the like may be combined as desired.

A method for retrieving assemblies 5 associated with Embodiment 1 as described above comprises Operation (A) in which semiconductor wafer 4 is secured to semiconductor backside protective film 11 at laminated bodies 71; Operation (B) in which hard support body 8 is secured to second adhesive layer 122 at laminated bodies 71; Operation (C) in which semiconductor wafer 4 which has semiconductor backside protective film 11 secured thereto is subjected to dicing to form assemblies 5; Operation (D) in which two-sided adhesive sheet 12 is heated following Operation (C); and Operation (E) in which assemblies 5 are detached from two-sided adhesive sheet 12 following Operation (D). A semiconductor device manufacturing method associated with Embodiment 1 comprises Operation (A) through Operation (E), and further comprises Operation (F) in which assembly 5 is secured to object 6 to be bonded.

### WORKING EXAMPLES

Below, exemplary detailed description of this invention is given in terms of preferred working examples. Note, however, that except where otherwise described as limiting, the materials, blended amounts, and so forth described in these working examples are not intended to limit the scope of the present invention thereto.

### Fabrication of Semiconductor Backside Protective Film

For every 100 parts by weight of the solids content—i.e., solids content exclusive of solvent—of acrylic-acid-ester-type polymer (Paracron W-197C; manufactured by Negami Chemical Industrial Co., Ltd) having ethyl acrylate and methyl methacrylate as principal constituents, 10 parts by weight of epoxy resin (HP-4700; manufactured by Dainippon Ink And Chemicals, Incorporated), 10 parts by weight of phenolic resin (MEH7851-H; manufactured by Meiwa Plastic Industries, Ltd.), 85 parts by weight of spherical silica (SO-25R; spherical silica having average particle diameter 0.5 μm; manufactured by Admatechs Company Limited), 10 parts by weight of dye (OIL BLACK BS; manufactured by Orient Chemical Industries Co., Ltd.), and 10 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to a release liner (polyethylene terephthalate film of thickness 50 μm which had been subjected to silicone mold release treatment), and this was dried for 2 minutes at 130° C. In accordance with the foregoing means, a film of average thickness 20 μm was obtained. A disk-shaped piece of film (hereinafter referred to in the Working Examples as “Semiconductor Backside Protective Film”) of diameter 230 mm was cut out of the film.

### Working Example 1

### —Fabrication of Laminated Body—

A hand roller was used to apply Semiconductor Backside Protective Film to the thermal release adhesive layer of a two-sided adhesive sheet (Revalpha 3195V; manufactured by Nitto Denko Corporation) to fabricate a laminated body in accordance with Working Example 1. The laminated body of Working Example 1 comprised two-sided adhesive sheet (Revalpha 3195V; manufactured by Nitto Denko Corporation) and Semiconductor Backside Protective Film secured to the thermal release adhesive layer of the two-sided adhesive sheet (Revalpha 3195V; manufactured by Nitto Denko Corporation).

### —Evaluation—

A wafer (silicon mirror wafer of thickness 0.2 mm, diameter 8 inches, the backside of which had been subjected to polishing treatment) was compression-bonded at 70° C. to Semiconductor Backside Protective Film of the laminated body of Working Example 1. A glass plate was pressed against two-sided adhesive sheet (Revalpha 3195V; manufactured by Nitto Denko Corporation) of the laminated body on a parallel plate to secure the glass plate to the two-sided adhesive sheet (Revalpha 3195V; manufactured by Nitto Denko Corporation). The wafer which was secured to the laminated body was subjected to dicing to form assemblies—each of which respectively comprised a silicon chip and post-dicing semiconductor backside protective film secured to the silicon chip. The glass plate was heated to 120° C. to lower the force of adhesion at the interface between the thermal release adhesive layer and the post-dicing semiconductor backside protective film. A pick-up device (SPA-300; Shinkawa Ltd.) was used to carry out pick-up of 100 assemblies without employment of a push-up needle. Pick-up characteristics were good, success rate being almost 100%.
Wafers were diced under the following conditions using a dicing apparatus having product name “DFD-6361” manufactured by Disco Corporation.
Dicing speed: 30 mm/sec
   Dicing blades:
      Z1: “203O-SE 27HCDD” manufactured by Disco Corporation
      Z2: “203O-SE 27HCBB” manufactured by Disco Corporation
   Dicing blade rotational speed:
      Z1: 40,000 r/min
      Z2: 45,000 r/min
   Cutting method: Step-cut
   Wafer chip size: 2.0 mm square

### Working Example 2

Except for the fact that “Revalpha 3198 manufactured by Nitto Denko Corporation” two-sided adhesive sheet was used instead of “Revalpha 3195V manufactured by Nitto Denko Corporation” two-sided adhesive sheet, a method identical to that of Working Example 1 was used to fabricate a laminated body in accordance with Working Example 2. A method identical to that at Working Example 1 was used to evaluate pick-up characteristics of Working Example 2.

### Comparative Example 1

—Fabrication of Semiconductor Backside Protective Film with Integral Dicing Tape—

A hand roller was used to apply Semiconductor Backside Protective Film to “V-8-AR manufactured by Nitto Denko Corporation” dicing tape (comprising a base layer of average thickness 65 μm and an adhesive layer of average thickness 10 μm) to fabricate a semiconductor backside protective film with integral dicing tape. The semiconductor backside protective film with integral dicing tape comprised “V-8-AR manufactured by Nitto Denko Corporation” dicing tape and Semiconductor Backside Protective Film secured to the adhesive layer.

### —Evaluation—

A wafer (silicon mirror wafer of thickness 0.2 mm, diameter 8 inches, the backside of which had been subjected to polishing treatment) was compression-bonded at 70° C. to the semiconductor backside protective film with integral dicing tape. The wafer which was secured to the Semiconductor Backside Protective Film was subjected to dicing to form assemblies—each of which respectively comprised a silicon chip and post-dicing semiconductor backside protective film secured to the silicon chip. A pick-up device (SPA-300; Shinkawa Ltd.) was used, with nine needles being employed for push-up of assemblies under conditions such that needle push-up amount was 500 μm, push-up speed was 20 mm/sec, and push-up time was 1 sec to detach the assemblies from the dicing tape. Success rate for pick-up of 100 assemblies was calculated. Pick-up characteristics were good, success rate being almost 100%.
Wafers were diced under the following conditions using a dicing apparatus having product name “DFD-6361” manufactured by Disco Corporation.
Dicing speed: 30 mm/sec
   Dicing blades:
      Z1: “203O-SE 27HCDD” manufactured by Disco Corporation
      Z2: “203O-SE 27HCBB” manufactured by Disco Corporation
   Dicing blade rotational speed:
      Z1: 40,000 r/min
      Z2: 45,000 r/min
   Cutting method: Step-cut
   Wafer chip size: 2.0 mm square

TABLE 1

| | Working | Working | Comparative |
|---|---|---|---|
| | Example 1 | Example 2 | Example 1 |
| Pick-up success rate % | 100 | 100 | 50 |

### EXPLANATION OF REFERENCE NUMERALS

1 Composite body
11 Semiconductor backside protective film
12 Two-sided adhesive sheet
121 First adhesive layer
122 Second adhesive layer
123 Base layer
13 Release liner
14 Release liner
71 Laminated bodies
4 Semiconductor wafer
5 Assembly
6 Object to be bonded
8 Support body
41 Semiconductor chip
51 Bump
61 Electrically conductive material
111 Post-dicing semiconductor backside protective film
125 Third adhesive layer
126 Rubber-like organic elastic layer

1. A laminated body comprising
a two-sided adhesive sheet; and
a semiconductor backside protective film arranged over the two-sided adhesive sheet;
wherein the two-sided adhesive sheet comprises a first adhesive layer, a second adhesive layer, and a base layer disposed between the first adhesive layer and the second adhesive layer;
wherein the first adhesive layer is disposed between the semiconductor backside protective film and the base layer; and
the first adhesive layer has a property such that application of heat thereto causes reduction in peel strength thereof.

2. The laminated body according to claim 1 wherein the first adhesive layer comprises thermally expansible microspheres that expand as a result of application of heat thereto.

3. The laminated body according to claim 2 wherein a temperature for initiating thermal expansion of the thermally expansible microspheres is not less than 90° C.

4. The laminated body according to claim 2 wherein bulk modulus of the thermally expansible microspheres is not less than 5.

5. The laminated body according to claim 2 wherein
the two-sided adhesive sheet further comprises a non-thermally-expansible third adhesive layer; and
the third adhesive layer is disposed between the first adhesive layer and the semiconductor backside protective film.

6. The laminated body according to claim 2 wherein the two-sided adhesive sheet further comprises a rubber-like organic elastic layer disposed between the first adhesive layer and the base layer.

7. A composite body comprising
a release liner; and
the laminated body according to claim 1 arranged over the release liner.

8. A method for retrieving an assembly comprising a semiconductor chip and a post-dicing semiconductor backside protective film secured to the semiconductor chip, the assembly retrieval method comprising:
an operation in which a semiconductor wafer is secured to the semiconductor backside protective film of the laminated body according to claim 1;
an operation in which a hard support body is secured to the second adhesive layer of the laminated body;
an operation in which the semiconductor wafer secured to the semiconductor backside protective film is subjected to dicing to form the assembly;
an operation in which, following the operation in which the assembly is formed, the two-sided adhesive sheet is heated; and
an operation in which, following the operation in which the two-sided adhesive sheet is heated, the assembly is detached from the two-sided adhesive sheet.

9. A semiconductor device manufacturing method comprising an operation in which the assembly retrieved by the assembly retrieval method according to claim 8 is secured to an object to be bonded.
